(19) United States
(12) Patent Application Publication
(10) Pub. No.: US 2021/0268693 A1
(43) Pub. Date: Sep. 2, 2021

(54) A NANOCOMPOSITE MOLD FOR THERMAL NANOIMPRINTING AND METHOD FOR PRODUCING THE SAME

(71) Applicant: B.G. NEGEV TECHNOLOGIES AND APPLICATIONS LTD., AT BEN-GURION UNIVERSITY, Beer-Sheva (IL)

(72) Inventors: Mark SCHVARTZMAN, Tel Aviv (IL); Viraj BHINGARDIVE, Beer-Sheva (IL); Liran MENAHEM, Hadera (IL)

(21) Appl. No.: 17/259,048

(22) PCT Filed: Jul. 3, 2019
(86) PCT No.: PCT/IL2019/050738

§ 371 Date: Jan. 8, 2021

Related U.S. Application Data
(60) Provisional application No. 62/695,864, filed on Jul. 10, 2018.

(51) Int. Cl. B29C 33/38

(52) U.S. Cl. CPC B29C 33/3842; B29K 2083/00; B29C 2033/385

(57) ABSTRACT

The invention relates to a nanocomposite elastic mold for thermal nanoimprint, the mold comprising an elastic substrate, to which a plurality of rigid individual nanofeatures are bonded. The bonding of the rigid individual nanofeatures to the elastic substrate is performed by a process which uses a sacrificial substrate and a sacrificial coating.

### FIELD OF THE INVENTION

The invention relates in general to the field of nanoimprinting. More specifically, the invention relates to a nanocomposite mold for use in thermal nanoimprinting.

### BACKGROUND OF THE INVENTION

Nanoimprint is a technique which is widely used for shaping in a nano-scale surfaces of tiny articles, such as, optical components, electronic devices, photonic nanostructures, etc. Soft nanoimprinting is a versatile, high-throughput, and cost-effective nanolithography technique in which a nanoscale pattern is mechanically transferred onto a resist by an elastomeric mold. Today, elastomeric molds are commonly produced from a soft (flexible) material, such as polydimethylsiloxane (PDMS). Elastomeric molds have numerous advantages over its rigid counterparts made of, for instance, Si, quartz, or Ni. In particular, elastomeric molds are much less sensitive to surface contaminants compared to rigid molds, so that nanopatterns that are produced by elsatomeric molds are practically free of defects. In addition, a nanoimprint by a flexible mold can be performed by a gentle press, for example, by the thumb, in contrast to a high pressure which is required in rigid-mold nanoimprinting. Finally, elastomeric molds can be applied to non-planar surfaces, an advantage which is particularly important in the production of functional nanostructures on curved or flexible substrates. However, a flexible nanoimprint process typically has several drawbacks, the most notable of which is the inability of an elastomeric mold to produce nanopatterns with a sub-100 nm resolution. This limitation stems from the low modulus of the used elastomeric materials such as PDMS, whose relief features deform and collapse during imprinting. Notably, such a limitation does not exist in nanoimprint with rigid molds, where features that can be down-sized to several nanometers can be fabricated. Odom et al. “Improved Pattern Transfer in Soft Lithography Using Composite Stamps”, Langmuir 2002, 18, 5314-5320, has suggested a hybrid mold with an elastomeric substrate and an image layer made of hardened elastomer. The mold of Odom is in fact a semi-flexible mold which is composed of two PDMS layers: a first, flexible PDMS layer, and a second hardened PDMS layer which serves as an image layer. The protrusions of the image layer are typically carved within the hardened layer, therefore forming a unitary hardened layer which includes nanofeatures. While the mold of Odom can be used for nanoimprint with a sub-100 nm resolution, some limitations remain with respect to the use of such hybrid molds: Odom indicates that the hybrid mold typically generates cracks in the hard image layer. Later, Li et al., “Hybrid Nanoimprint-Soft Lithography with Sub-15 nm Resolution”, Nano Lett. 2009, 9, 2306-2310, have reported a semi-flexible mold substantially in the same structure of Odom, which is composed of a PDMS substrate and an image layer made of a photocurable polymer, demonstrating a sub-15 nm resolution with the ability to imprint on a surface of an optical fiber. However, while this mold can form a conformal contact with a fiber by bending around its cylindrical surface, still an imprint on a surface with a more complex curvature, such as a lens or saddle, requires an in-plane stretching of the mold, which is practically impossible for this type of hybrid mold having a continuous, stiff image layer.

In addition to resolution, nanoimprint molds are also examined in terms of their compatibility with different imprint resists. In this regard, rigid molds that can be used with both ultraviolet (UV) curable and thermal resists, are highly advantageous over soft molds that are limited to only UV curable resists. The incompatibility of soft nanoimprint molds with thermal resists stems from the fact that a typical thermal resist, such as commonly used PMMA, has an elastic modulus of 1-3 MPa when heated to its imprint temperature of 160-200° C. This modulus is similar to that of the used elastomer for soft molds, such as PDMS. Thus, when the relief features of elastomeric mold are pressed against a viscous resist, they do not completely penetrate the resist, but rather deform and collapse. This feature deformation leads to a significant distortion of the imprinted pattern. Therefore, the incompatibility of soft nanoimprint with thermal resists has precluded many of its important applications, such as direct embossing of curved thermoplastic substrates.

It is therefore an object of the present invention to provide a soft nanoimprint mold that can operate with a thermal resist.

It is still another object of the invention to provide a soft nanoimprint mold that can provide a resolution as low as tens of nanometers, when operating with a thermal resist.

It is still another object of the invention to provide a soft nanoimprint mold that can be applied on articles of sharp curvatures in a thermal resist environment.

It is still another object of the invention to provide a method for producing the soft mold of the invention having the characteristics mentioned above.

Other objects and advantages of the invention will become apparent as the description proceed.

### SUMMARY OF THE INVENTION

The invention relates to a method for producing a nanocomposite elastic mold for thermal nanoimprinting, comprising: (a) providing a sacrificial rigid substrate which is made of a rigid material; (b) coating the rigid sacrificial substrate by a sacrificial coating; (c) attaching a rigid image layer to the sacrificial coating; (d) shaping a plurality of individual nanofeatures within the rigid layer; covering the nanofeatures by an adhesive layer; (e) separating an intermediate unit from a structure formed so far, said intermediate unit comprising said sacrificial coating, said adhesive layer, and said individual nanofeatures that are contained within said adhesive layer; (f) removing said sacrificial coating from said intermediate unit to form a remained intermediate unit; (g) attaching said remained intermediate unit to an elastic substrate; and (h) removing said adhesive layer to form said nanocomposite elastic mold.

In one embodiment of the invention, said rigid sacrificial substrate is silicon.

In one embodiment of the invention, said sacrificial coating is made of a material having a poor adhesion to said sacrificial substrate, thereby to facilitate detachment of the sacrificial coating at a later stage.

In one embodiment of the invention, said sacrificial coating is made of gold.

In one embodiment of the invention, said rigid image layer is made of a material whose stiffness is at least one order of magnitude higher than that of said elastic substrate.

In one embodiment of the invention, said rigid image layer is made of silica.

In one embodiment of the invention, said adhesive layer is made of a material whose adhesion to the sacrificial coating is higher than the adhesion between the sacrificial coating and the sacrificial substrate, thereby to facilitate said later separation.

In one embodiment of the invention, said adhesive layer is made of a PMMA.

In one embodiment of the invention, said elastic substrate is made of an elastomeric material.

In one embodiment of the invention, said elastic substrate is made of PDMS.

In one embodiment of the invention, said shaping of the plurality of individual nanofeatures is made by means of a micro or nano lithography.

In one embodiment of the invention, said shaping of the plurality of individual nanofeatures is made by means of an electron-beam lithography.

In one embodiment of the invention, said sacrificial coating is removed by means of etching.

In one embodiment of the invention, said adhesive layer is removed by means of a rinsing liquid.

In one embodiment of the invention, the rinsing liquid is acetone.

In one embodiment of the invention, said adhesive layer is made of a material soluble in water or another organic or inorganic solvent, and wherein said adhesive layer is removed by means of water or a solvent.

In one embodiment of the invention, the elasticity of the elastic substrate is in the range of 0.05 MPa to 8 MPa.

In one embodiment of the invention, the rigidity of the individual nanofeatures is larger than that of the elastic substrate by at least one order of magnitude.

The invention also relates to a nanocomposite elastic mold for thermal nanoimprint, the mold comprising an elastic substrate, to which a plurality of rigid individual nanofeatures are bonded.

In one embodiment of the invention, the rigidity of the individual nanofeatures is larger than that of the elastic substrate by at least one order of magnitude.

In one embodiment of the invention, said individual nanofeatures are made of silica.

In one embodiment of the invention, said elastic substrate is made of an elastomeric material.

In one embodiment of the invention, said elastic substrate is made of PDMS.

In one embodiment of the invention, the elasticity of the elastic substrate is in the range of 0.05 MPa to 8 MPa.

### BRIEF DESCRIPTION OF THE DRAWINGS

In the drawings:

FIG. 1a generally illustrates a typical prior art nanoimprint mold, when applied to a cylindrical body;

FIG. 1b generally illustrates a typical prior art nanoimprint mold, when applied to a semi-spherical body;

FIG. 1c generally illustrates a prior art hybrid nanoimprint mold.

FIG. 2 generally illustrates the basic structure of a nanocomposite mold, according to an embodiment of the present invention;

FIGS. 3a to 3g generally illustrates one exemplary process for fabricating the mold of the present invention;

FIGS. 4a to 4k generally illustrates a more specific exemplary process for fabricating the mold of the present invention;

FIGS. 5a and 5b show 2D and 3D representative AFM images, respectively, of the nanocomposite flexible mold of the invention;

FIG. 6 shows a comparison of nanoimprinted arrays of circular features, as produce by a prior art mold, and as produced by a mold according to an embodiment of the present invention.

FIG. 7 shows a comparison between a substrate which was imprinted by a mold of the prior art and between a substrate which was imprinted by a mold of the present invention;

FIG. 8a schematically illustrates a nanoimprint procedure using a mold according to an embodiment of the present invention; and

FIG. 8b shows a SEM image of a semi-spherical lens, as imprinted by a mold according to an embodiment of the present invention.

### DETAILED DESCRIPTION OF PREFERRED EMBODIMENTS

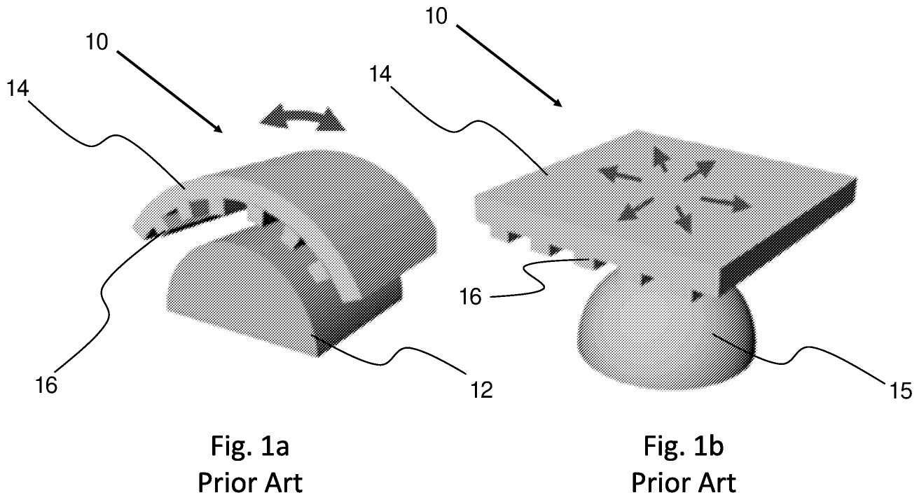

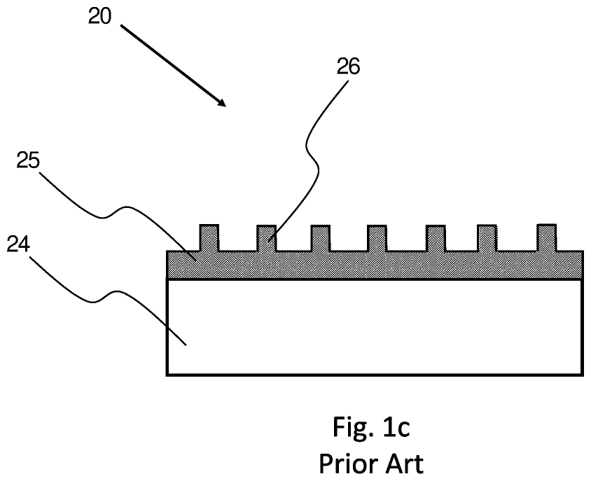

As noted above, nanoimprinting of curved objects requires elastic molds. FIG. 1a generally illustrates a typical mold 10 of the prior art for imprinting on a curved cylindrical fiber 12. The mold 10 is composed of a layer 14, which is carved to produce protrusions 16 of any shape. FIG. 1b similarly shows the prior art mold 10, when applied to a semi-spherical body (such as a lens) 15. The use of existing elastic molds for nanoimprinting is impractical in a thermal resist environment, as the surface of the mold deforms when pressed against a viscous resist, significantly corrupting the plane of contact of the mold, thereby substantially reducing the quality of imprinting. FIG. 1c shows a structure of a hybrid, semi-flexible mold 20 for nanoimprinting, as described, for example, by Odom et. al. and by Li et. al (mentioned in the “Background of the Invention” section above). The hybrid mold 20 consists of a flexible base layer 24 which is made of PDMS, and an image layer 25 which is made of hardened (less flexible) PDMS. The protrusions 26 of the image layer 25 are typically carved within the hardened layer, therefore forming a unitary hardened layer with protrusions. In view of the flexible layer 24, and the hardened layer 25 the hybrid mold 200 is in fact a semi-flexible mold.

The present invention overcomes the drawbacks of the prior art molds for thermal nanoimprinting by providing a novel soft (flexible) nanocomposite mold for operation with thermal resists in a nanoscale resolution.

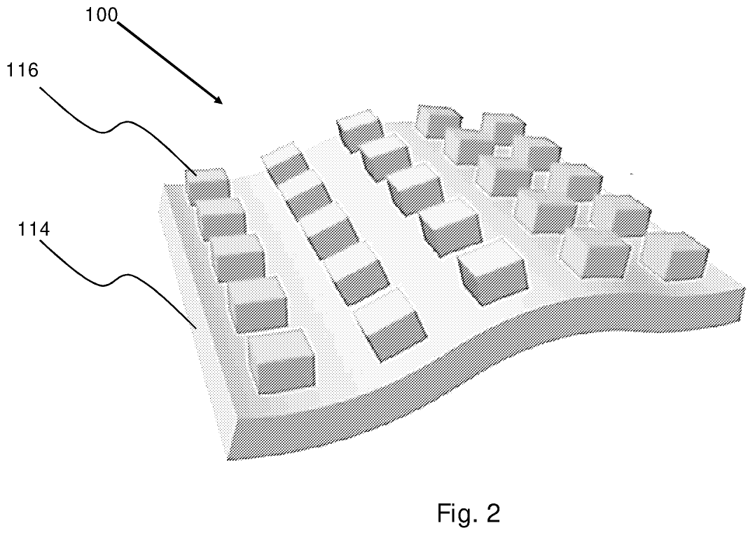

FIG. 2 shows a basic structure of a nanocomposite mold 100, according to an embodiment of the present invention. Mold 100 is basically composed of an elastic layer 114, to which a plurality of individual rigid nanofeatures 116 are bonded. The term “individual nanofeatures” refers herein to a plurality of nanofeatures that are separated from one another in terms of not being connected by a material from which they are made.

In a more specific embodiment of the invention, the nanocomposite mold 100 is composed of an elastic polydimethylsiloxane (PDMS)layer 114, onto which individual rigid silica nanofeatures 116 are chemically bonded. By “elastic layer” it is meant herein a layer typically having elasticity in the range of between of 0.05 MPa to 8 MPa. The rigidity of the objects 116 ensures a robust pattern-transfer into a thermal resist, with a pattern fidelity that is comparable to hard nanoimprint. The nanocomposite molds 100 of the invention may include a variety of nano-patterns of different sizes and shapes.

As will be shown hereinafter, the inventors have found that the nanocomposite mold 100 of the invention can thermally imprint sub-100 nm objects, while conventional flexible PDMS molds are entirely incompatible with thermal resists. The nanocomposite mold 100 of the invention was used to imprint a thermoplastic film on a lens, the first case in which a thermal nanoimprint on such a curved substrate was performed by a flexible mold.

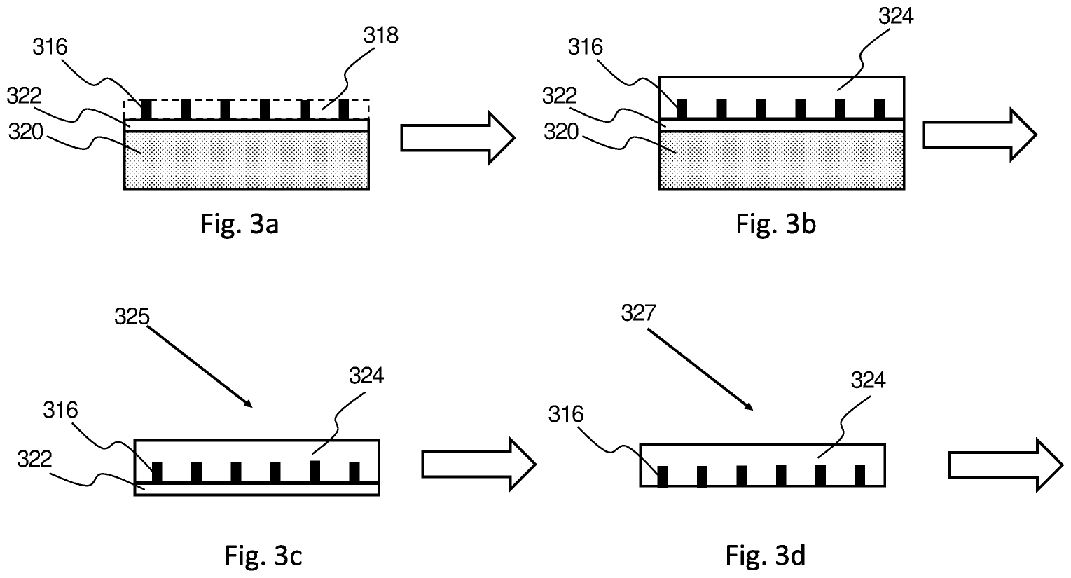

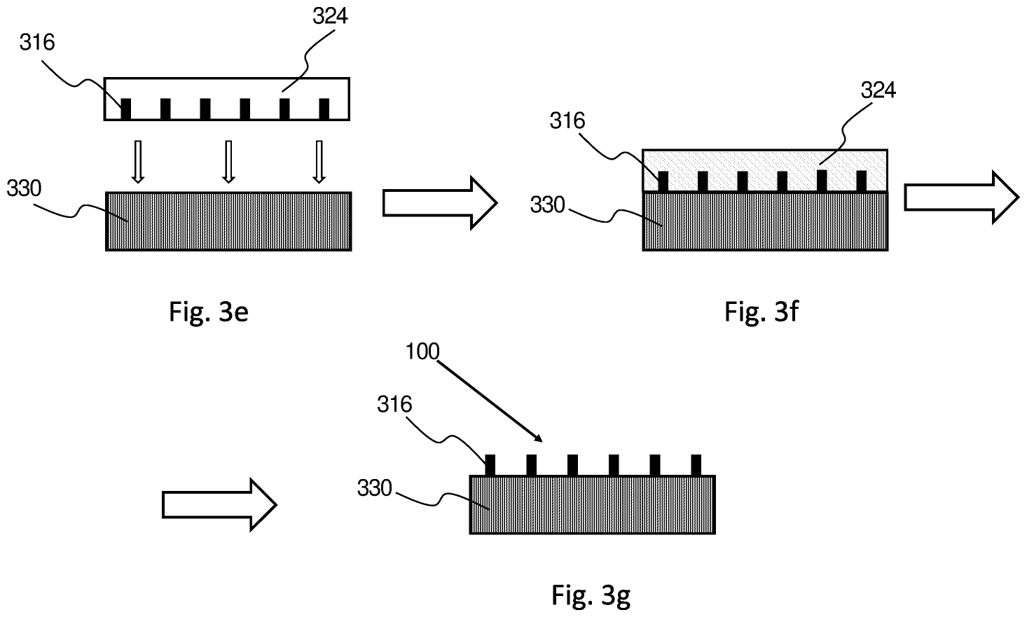

Rigid nanofeatures cannot be directly fabricated on elastomeric substrates for several reasons. First, many elastomeric materials, such as PDMS, have a very low surface energy, therefore any deposited thin film will poorly adhere to it. Moreover, thin films deposited onto elastomers often crack due to the surface elasticity, even when well adhered. Finally, the elastomeric materials swell in various organic solvents. Therefore, the combining of rigid nanofeatures with a PDMS substrate requires a unique approach which has never been suggested by the prior art. FIGS. 3a to 3g generally illustrate a pattern transfer process for fabricating the mold 100, according to an embodiment of the invention. In a first step, a rigid sacrificial unit is prepared. The sacrificial unit consists of a rigid sacrificial substrate 320, which is coated by a sacrificial coating 322. The sacrificial coating is made of a material having a poor adhesion to the sacrificial substrate 320, thereby to facilitate detachment of the sacrificial coating at a later stage. In a next step, a rigid image layer 318 of rigid material is attached to the sacrificial coating 322. The rigid image layer is made of a material whose stiffness is at least one order of magnitude higher than that of the elastic substrate 330 (see FIG. 3e). The procedure of FIG. 3a in itself is performed in a similar manner typically done during production of rigid molds of the prior art. In a next step, the rigid layer 318 is patterned by lithography to produce individual nanofeatures 316 of any desired shape, while removing any material of layer 318 in between the individual nanofeatures 316. The nanofeatures 316 are also arranged in any desired pattern. In the next step shown in FIG. 3b, an adhesive layer 324, originally in a liquid or gel form, is applied above and around the individual nanofeatures 316. Later on, the adhesive layer 324 solidifies. The adhesive layer is typically made of a material whose adhesion to the sacrificial coating 322 is higher than the adhesion between the sacrificial coating 322 and the sacrificial substrate 320, thereby to facilitate a later separation. Next, upon solidification, an “intermediate unit” 325 which consists of the adhesive layer 324, the nanofeatures 316, and the sacrificial coating 322, is detached from the sacrificial substrate 320 (shown in FIG. 3c). Next, the sacrificial coating 322 is removed (for example, by etching) from the intermediate unit 325, to form a “remained intermediate unit” 327 (FIG. 3d). The “remained intermediate unit” 327, which consists the adhesive layer 324 with the nanofeatures 316 contained in it, is then attached (FIG. 3e) to a flexible substrate 330, to form a “unified piece” which includes the flexible substrate 330, and the adhesive layer 324 with the nanofeatures 316 contained in it (FIG. 3f). The Then, in a final stage the process continues by removing the adhesive layer 324, for example, by means of a solvent, thereby to reach the final flexible nanoimprint mold 100 of FIG. 3g, which consists the flexible layer 330, and the plurality of rigid individual nanofeatures 316 that are attached to one surface of the layer 330.

Examples and Experiments

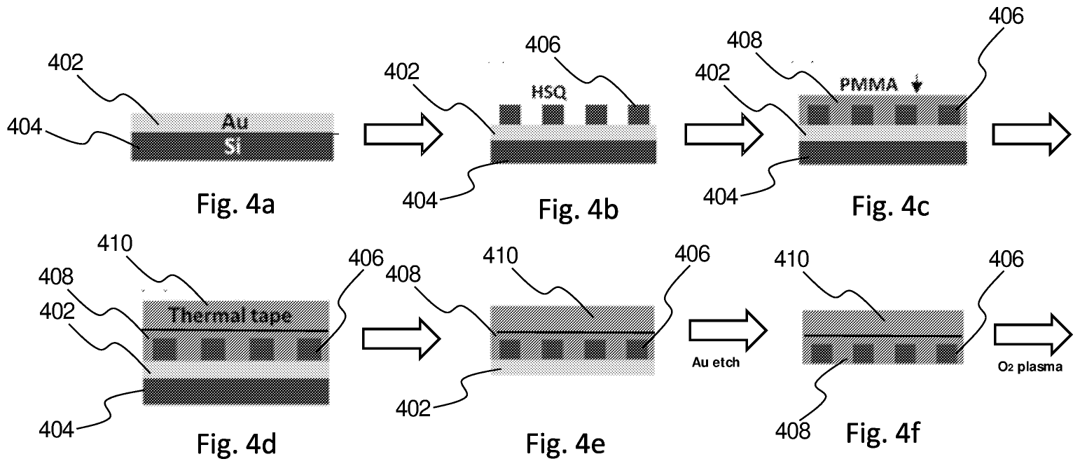

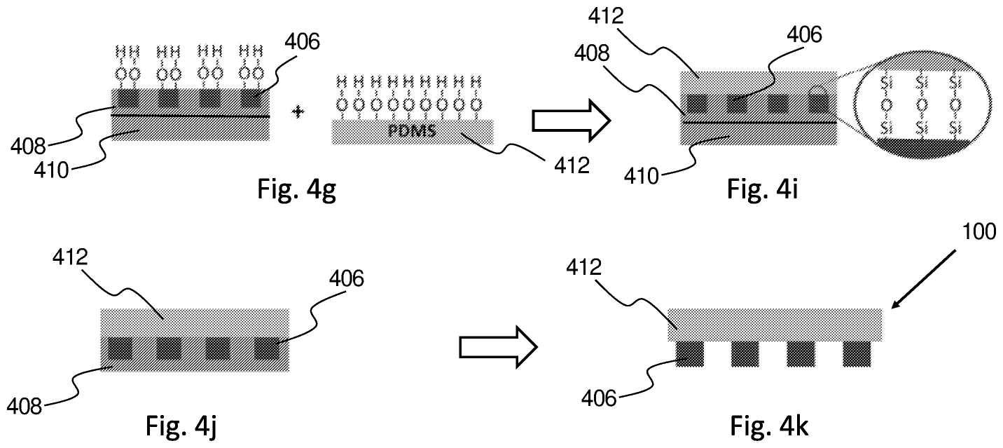

In one aspect, the invention relates to a method for fabricating a flexible mold which consists of a PDMS layer with nanosized rigid relief objects made of cured spin-on-glass material. FIGS. 4a to 4k generally describe this exemplary method. It should be noted that the exemplary method is based on specific experiments, while the actual parameters indicated therein may vary when practically carrying out the invention. First, a 40 nm thick Au (gold) film 402 is evaporated on a sacrificial silicon substrate 404 (equivalent to the sacrificial substrate 320 of FIG. 3a). The Au is deposited directly on the silicon substrate 404 without any adhesion layer. In a next step (FIG. 4b) a film of hydrogen silsesquioxane (HSQ, XR-1541, Dow Corning) is applied over the Au film. Next, the HSQ film is patterned using, for example, an electron-beam lithography which exposes it in a Raith E-line system, developing it in TMAH solution (AZ 726, Rohm and Haas) for 2 minutes, rinsing it in DI water, and drying it. HSQ is widely used as a spin-on-glass precursor. The HSQ is also a well-known as an inorganic electron beam resist having an excellent resolution in view of its cage-like molecular structure which transforms into a cross-linked network when facing an electron beam radiation. The HSQ is also an optimal material for ultra-small silica nanofeatures directly fabricated by lithography and without any complementary pattern-transfer process such as plasma etching. To complete the transformation of the electron-beam-exposed HSQ to nonstoichiometric silicon oxide, the HSQ is thermally annealed for 30 minutes at 330° C. and then ashed in oxygen plasma (Harrick PDC-32G, 1 min.), thereby forming the nanofeatures 406 (316 in FIG. 3b) that are attached to the Au layer 402 (which is equivalent to the sacrificial coating 322). In a next step, a thin film 408 of PMMA (A6, 495K, Microchem GmbH) is applied by a spin coating procedure and baked for 2 minutes at 180° C. A thermal tape 410 (Revapha, Nitto Denko) is then attached to the PMMA layer 408 (FIG. 4d), and is used to peel the entire structure (namely, the PMMA layer 408, the nanofeatures 406, and the Au layer 402—also referred to as the “intermediate unit” 325 in FIG. 3c) from the Si wafer 404 (FIG. 4e). Then, the Au film 402 (namely, the “sacrificial coating”) is stripped by immersing the structure within a standard iodine-based etchant, potassium iodide (KI) for half a minute, followed by immediate rinsing in DI water and nitrogen drying (FIG. 4f). To attach the HSQ nanofeatures to a premade elastic PDMS substrate 412 (Sylgard 184, Dow corning), both the thermal tape with the embedded HSQ nanofeatures and the PDMS substrate 412 are exposed to oxygen plasma (Harrick PDC-32G, 1 min.), which activates their surfaces with hydroxyl groups (FIG. 4g). Immediately after the plasma exposure, the two surfaces are gently pressed against each other for 1s, for example, using the thumb, and baked overnight in an oven at 60° C. (FIG. 4i). No additional pressure needs to be applied on the substrates during baking. Next, the thermal tape is detached (FIG. 4j) by briefly heating the sample to 110° C. using a hot plate. Finally, the PMMA layer 408 is removed by rinsing it with acetone to reach the final flexible mold 100 of the invention (FIG. 4k). The flexible mold 100 of the invention consists of a flexible layer 412, with rigid nanofeatures that are attached to it.

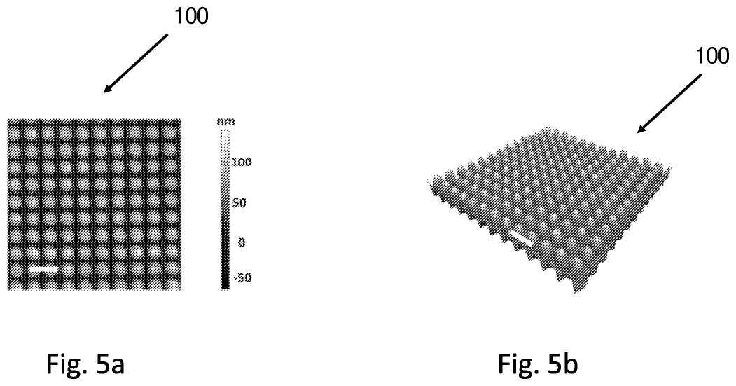

The completion of the transfer of the HSQ features 406 onto the PDMS substrate 412 according to the method described above was verified by scanning the surface of the mold 100 by an atomic force microscope (AFM). FIGS. 5a and 5b show 2D and 3D representative AFM images, respectively, of a nanocomposite flexible mold 100 with HSQ relief nanofeatures 406 that were chemically attached to a PDMS surface using the above described pattern transfer process. The HSQ nanofeatures 406 were compared before and after the transfer, and it was found that their shape, size, height, and morphology have not been changed during the transfer. It was also found that the produced composite structure is highly robust. For instance, neither high-power sonication for 10 minutes, nor exposure to a temperature higher than 100° C. caused any observable damage to the mold 100. It is believed that this robustness stems from strong and irreversible Si—O—Si covalent bonds formed at the PDMS-HSQ interface. While PDMS is known to swell in organic liquids including acetone, it was found that the short exposure of the mold 100 to acetone during the last fabrication step did not lead to any observable morphology change, neither to the PDMS surface 412 nor to the HSQ nanofeatures 406. Furthermore, any possible swelling of PDMS can be prevented, for example, by use of water-soluble polymer such as polyvinyl alcohol (PVA) as an alternative to the PMMA.

In order to ensure that the detachment of the HSQ relief nanofeatures from a resist is easy and robust, a fabricated mold was tested in a mold release agent based on a fluorinated silane monolayer (Nanonex NXT 110). Such fluorinated silanes are extensively used as mold release agents for Si and SiO₂-based molds. Furthermore, same mold release agents were shown to be effective for Si molds with relief features made from electron-beam patterned and thermally cured HSQ. It is believed that organic silanes form a self-assembled monolayer on a HSQ surface, as they do on a silica surface, as the composition of cured and plasma-treated HSQ is close to that of silica. This observation was recently confirmed by demonstrating that polyethylene glycol silanes can chemically passivate a surface of cured HSQ.

To demonstrate the applicability of the nanocomposite molds 100 for thermal nanoimprint, the inventors used polybenzylmethacrylate (PBMA) as a thermal resist. The PBMA was chosen in view of its relatively low glass transition point of 54° C., which allows thermal nanoimprint at a temperature below 100° C. Such a low imprint temperature can prevent any substantial change to the mechanical properties of the PDMS due to overheating. The PBMA was diluted in toluene, then it was spin-coated by a silicon substrate, and baked at 100° C. for 2 minutes. A Nanonex XB200 imprint tool was used for a nanoimprinting. The typical process parameters included a temperature of 90° C., pressure of 100 psi, and process time of 5 minutes. For each mold, a PBMA film was applied with a thickness slightly higher than the height of the mold nanofeatures, thereby to ensure robust polymer flow during the imprint and to prevent air trapping between the nanofeatures.

To explore the resolution limits of the mold of the invention in a soft thermal nanoimprint, the inventors fabricated several nanocomposite PDMS-HSQ molds that are patterned with arrays of rectangular or circular nanofeatures of various sizes. To further demonstrate the uniqueness of the elastic mold of the invention in thermal nanoimprint, the inventors compared nanoimprinted patterns by the mold of the invention to patterns imprinted by conventional PDMS molds.

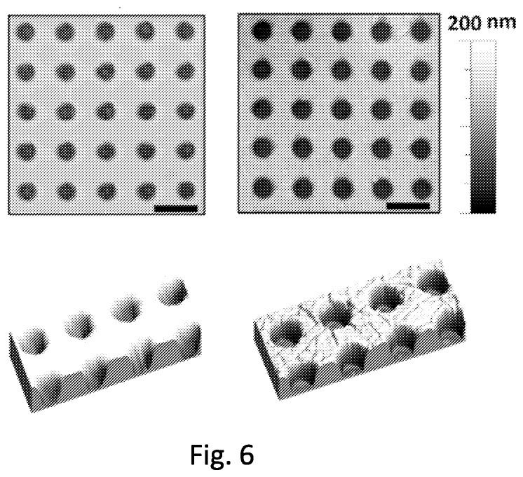

FIG. 6 shows a comparison of nanoimprinted arrays of circular features having a diameter of 1 μm, as produced by a conventional (prior art) PDMS mold, and a nanocomposite PDMS-HSQ mold according to the present invention. FIG. 6 shows: (a) top left: an AFM image of a substrate after being imprinted by an elastic PDMS mold of the prior art; (b) bottom left: a cross-sectional view of the substrate as imprinted by said conventional PDMS mold; (c) top right: an AFM image of a substrate as imprinted by a PDMS-HSQ nanocomposite mold of the invention; and (d) bottom right: a cross-sectional view of the substrate as imprinted by said nanocomposite PDMS-HSQ nanocomposite mold of the invention. The scale for all the images is 2 μm. As shown, the features imprinted by the conventional PDMS mold barely replicate the circular shape of the mold. These imprinted features by the prior art mold have a substantially conical shape, as seen in the cross-sectional AFM image (most probably due to deformation of the relief features pressed against the viscous resist). In contrast, the features imprinted by the nanocomposite PDMS-HSQ mold of the invention precisely reproduced the mold geometry. Notably, few cracks are visible on the surface of the PBMA substrate that was imprinted by the nanocomposite mold of the invention.

The inventors believe that the cracks replicate defects in the mold surface, that could have formed either by oxygen plasma or as a result of PDMS swelling in the solvent of the mold release agent. These cracks increase the overall surface roughness of the imprinted resist. Yet, the purpose of any patterned resist is to use it as a mask for a pattern transfer in a complementary process such as etching or liftoff. In this sense, the surface roughness of the top of the resist has no negative effect on the outcome of the pattern transfer. On the other hand, the surface roughness of the bottom of the imprinted features surely can form a negative effect on the process outcome, as it is transferred to the underlying substrate by plasma etching and forms a micrograss texture. The inventors have also estimated the surface roughness at the bottom of the nanoimprinted features in the two cases using AFM. It was found that the bottom of the substrate features as imprinted by a conventional PDMS mold has a root-mean-square roughness (RRMS) of 8.6 nm. This roughness is much higher than that of the PDMS features of the mold itself that had a RRMS of ˜1.2 nm. This roughness is most probably caused by the deformation of the PDMS relief features of the conventional mold during the imprint. On the contrary, the bottom surface of the features imprinted by the nanocomposite mold of the invention were found to be relatively smooth, with a low RRMS value of 2.2 nm. This low roughness is very close to the range of HSQ the nanofeatures, having a RRMS of ˜1.5 nm. Based on this finding, it was concluded that rigid relief features chemically attached to the soft PDMS substrate do not deform during the imprint, therefore they ideally transfer their pattern to the subjected substrate.

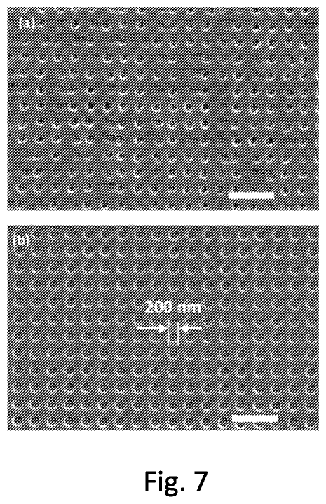

FIG. 7 shows a comparison between two imprinted substrates: Top: a substrate as imprinted by a conventional (prior art) flexible PDMS mold; and Bottom: a substrate as imprinted by a nanocomposite PDMS-HSQ mold of the invention (scale: 1 μm). The images were acquired by a scanning electron microscope. More specifically, the uniqueness of the present invention is highlighted by the reduction in the feature size. The arrays of FIG. 7 are of 200 nm-features that were thermally nanoimprinted within a PBMA substrate. The height of the features in both cases was 150 nm. It is clearly seen that the pattern produced by the conventional PDMS mold (top of FIG. 7) is highly distorted. Thus, at this size scale, conventional PDMS molds are completely incompatible with thermal resists. In contrary, the dimensions and shape of the features imprinted by the nanocomposite mold of the invention (bottom of FIG. 7) exactly reproduced that of the HSQ relief nanofeatures of the mold. Both images of FIG. 7 were acquired using a scanning electron microscopy (SEM) immediately after electron-beam lithography. To summarize, the nanocomposite mold of the invention which consists a PDMS substrate and rigid relief nanofeatures that are chemically attached to it seem to be the ultimate solution for a flexible thermal nanoimprint lithography with ultra-high patterning resolution.

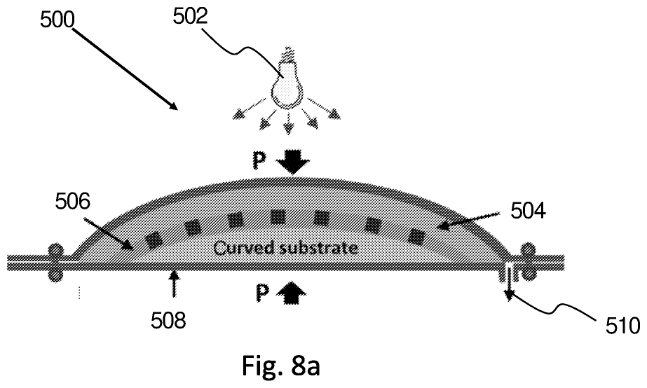

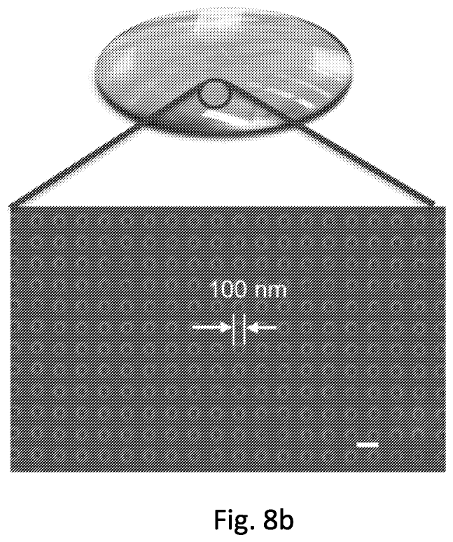

As according to the invention the soft thermal nanoimprint approach is based on a mold which is composed of an elastomeric substrate (330 or 412) and rigid relief nanofeatures (316 or 406), it uniquely combines the key advantages of both conventional rigid molds and soft imprint molds: (i) It has a high resolution compare to nanoimprinting with rigid molds; and (ii) it can produce a defect free conformal contact with an imprinted substrate, even when the substrate is not planar. It should be noted that the rigidity of the individual nanofeatures (316 or 406) is larger than that of the elastic substrate 330 by at least one order of magnitude. To demonstrate this unique and innovative combination, the inventors thermally nanoimprinted an ultra-high-resolution pattern on a surface of a lens. For this purpose, the inventors spin-coated and baked a PBMA film on a spherical lens having a diameter of 35 mm and a curvature radius of 50 mm. The inventors used a nanocomposite PDMS mold that contained 100 nm HSQ nanofeatures. The inventors performed the imprint procedure by placing a mold on top of the lens and by positioning the lens-mold sandwich between two membranes in a chuck of a Nanonex NX-B200 nanoimprint tool. The procedure 500 is schematically illustrated in FIG. 8a, where numeral 502 indicates an IR lamp, numeral 504 indicates the mold, numeral 506 indicates the resist, numeral 508 indicates the membrane, numeral 510 indicates a pump, and P indicates a pressure which is applied to the membranes from both sides. Procedure 500 has used the same parameters as used previously in the nanoimprint process that was performed on flat substrates. Neither macroscopic distortions nor wrinkles have been observed on the mold surface during the contact with the lens. After completion of the nanoimprint, the mold was gently separated from the lens surface. FIG. 8b shows a SEM image of the imprinted lens surface. Although the imprint process was performed on a curved surface, the quality of the transferred nanopattern was found to be excellent and comparable to commonly obtained high-resolution thermal nanoimprints on flat surfaces. SEM images that were taken from several locations of the lens indicated a negligible, few percents elongation of the array periodicity compared to its nominal value of 300 nm. This elongation was found the same in both x and y directions. This elongation can be explained as isotropic in-plane stretch of the mold that necessarily occurs when it conformally covers the lens curved surface. This stretch most likely creates shear forces at the PDMS-HSQ interface during the mold application. The forces, however, do not seem to affect the quality of the imprint or the reliability of the mold. As mentioned above, conventional (state of the art) flexible nanoimprint is incompatible with thermal resists because the polymeric resist and relief features of the elastomeric mold have similar elastic moduli. Thus, elastomeric relief features are not rigid enough to sustain the high capillary forces and pressure applied during the imprint. As a result, these features deform, resulting in pattern distortion. The prior art also disclosed hybrid molds containing image layers that are made from harder materials, such as hard PDMS and a photocurable polymer, whose moduli are 9 MPa and 216 MPa, respectively. The relief features made from these materials were stiff enough to produce quality nanopatterns within low-viscosity UV curable resists. However, it is assumed that the polymeric imaging features of the hybrid mold would be substantially softened while heated up to the imprint temperature if such molds were used in thermal nanoimprint. Therefore, they would fail to emboss a highly viscous thermal resist. In contrast to these hybrid molds, the mold of the present invention contains a plurality of individual nanofeatures that are made from cured HSQ, whose modulus after curing at 330° C. is ˜10 GPa, that is, a few orders of magnitude higher than that of features previously reported at the hybrid molds. Furthermore, due to its highly crosslinked structure, cured HSQ retains its mechanical properties when heated to 200° C. and above. Therefore, even when heated up to the temperature of thermal imprinting, the HSQ relief features remain stiff enough to sustain the nanoimprint pressure and to penetrate the viscous thermal resist, ensuring a pattern transfer with the highest possible fidelity. Notably, despite the rigid relief nanofeatures, the nanocomposite mold 100 of the present invention forms a robust conformal contact with the imprinted surface, and minimizes pattern defects.

While some embodiments of the invention have been described by way of illustration, it will be apparent that the invention can be carried into practice with many modifications, variations and adaptations, and with the use of numerous equivalents or alternative solutions that are within the scope of persons skilled in the art, without departing from the spirit of the invention or exceeding the scope of the claims.

1. A method for producing a nanocomposite elastic mold for thermal nanoimprinting, comprising:
a. providing a sacrificial rigid substrate which is made of a rigid material;
b. coating the rigid sacrificial substrate by a sacrificial coating;
c. attaching a rigid image layer to the sacrificial coating;
d. shaping a plurality of individual nanofeatures within the rigid layer;
e. covering the nanofeatures by an adhesive layer;
f. separating an intermediate unit from a structure formed so far, said intermediate unit comprising said sacrificial coating, said adhesive layer, and said individual nanofeatures that are contained within said adhesive layer;
g. removing said sacrificial coating from said intermediate unit to form a remained intermediate unit;
h. attaching said remained intermediate unit to an elastic substrate; and
i. removing said adhesive layer to form said nanocomposite elastic mold.

2. The method of claim 1, wherein said rigid sacrificial substrate is silicon.

3. The method of claim 1, wherein said sacrificial coating is made of a material having a poor adhesion to said sacrificial substrate, thereby to facilitate detachment of the sacrificial coating at a later stage.

4. The method of claim 1, wherein said sacrificial coating is made of gold.

5. The method of claim 1, wherein said rigid image layer is made of a material whose stiffness is at least one order of magnitude higher than that of said elastic substrate.

6. The method of claim 5, wherein said rigid image layer is made of silica.

7. The method of claim 1, wherein said adhesive layer is made of a material whose adhesion to the sacrificial coating is higher than the adhesion between the sacrificial coating and the sacrificial substrate, thereby to facilitate said later separation.

8. The method of claim 7, wherein said adhesive layer is made of a PMMA.

9. The method of claim 1, wherein said elastic substrate is made of an elastomeric material.

10. The method of claim 1, wherein said elastic substrate is made of PDMS.

11. The method of claim 1, wherein said shaping of the plurality of individual nanofeatures is made by means of a micro or nano lithography.

12. The method of claim 1, wherein said shaping of the plurality of individual nanofeatures is made by means of an electron-beam lithography.

13. The method of claim 1, wherein said sacrificial coating is removed by means of etching.

14. The method of claim 1, wherein said adhesive layer is removed by means of a rinsing liquid.

15. The method of claim 14, wherein the rinsing liquid is acetone.

16. The method of claim 1, wherein said adhesive layer is made of a material soluble in water or another organic or inorganic solvent, and wherein said adhesive layer is removed by means of water or a solvent.

17. The method of claim 1, wherein the elasticity of the elastic substrate is in the range of 0.05 MPa to 8 MPa.

18. The method of claim 1, wherein the rigidity of the individual nanofeatures is larger than that of the elastic substrate by at least one order of magnitude.

19. A nanocomposite elastic mold for thermal nanoimprint, comprising an elastic substrate, to which a plurality of rigid individual nanofeatures are bonded.

20. The nanocomposite elastic mold of claim 19, wherein the rigidity of the individual nanofeatures is larger than that of the elastic substrate by at least one order of magnitude.

21. The nanocomposite mold of claim 19, wherein said individual nanofeatures are made of silica.

22. The nanocomposite mold of claim 19, wherein said elastic substrate is made of an elastomeric material.

23. The nanocomposite mold of claim 19, wherein said elastic substrate is made of PDMS.

24. The nanocomposite mold of claim 18, wherein the elasticity of the elastic substrate is in the range of 0.05 MPa to 8 MPa.
